(19) United States
(12) Patent Application Publication
(10) Pub. No.: US 2017/0111060 A1
(43) Pub. Date: Apr. 20, 2017

(54) METHOD AND DEVICE FOR PERFORMING POLAR CODES CHANNEL-AWARE PROCEDURE

(71) Applicant: MACRONIX INTERNATIONAL CO., LTD., Hsinchu (TW)

(72) Inventors: Yu-Ming Huang, Taipei City (TW); Hsiang-Pang Li, Zhubei City (TW); Hsie-Chia Chang, Hsinchu City (TW)

(21) Appl. No.: 14/995,228

(22) Filed: Jan. 14, 2016

Related U.S. Application Data
(60) Provisional application No. 62/241,793, filed on Oct. 15, 2015.

(51) Int. Cl. H03M 13/13; H03M 13/45

(52) U.S. Cl. CPC H03M 13/13; H03M 13/45

(57) ABSTRACT

A method and a device for performing a polar codes channel-aware procedure are provided. A plurality of bit-channels have a polar code construction which is dynamic. The method includes the following steps. A plurality of reliability indices of some of the bit-channels are ranked. Whether an updating condition is satisfied is determined according to a ranking sequence of the reliability indices. If the updating condition is satisfied, the polar code construction is updated according to the ranking sequence of the reliability indices.

This application claims the benefit of U.S. provisional application Ser. No. 62/241,793, filed Oct. 15, 2015, the subject matter of which is incorporated herein by reference.

### BACKGROUND

Technical Field

The disclosure relates in general to a method and a device for performing an error-correcting procedure, and more particularly to a method and a device for performing a polar codes channel-aware procedure on a plurality of bit-channels having a polar code construction which is dynamic.

Description of the Related Art

Polar code is an advanced error-correcting code. In the case of storage (or communication), polar code polarizes some memory cells (or communication channels) into high reliable bit-channels and polarizes some memory cells (or communication channels) into low reliable bit-channels. The information is stored (or sent) via the high reliable bit-channels. Therefore, the bit error rate (BER) can be greatly reduced to achieve excellent reliability.

### SUMMARY

The disclosure is directed to a method and a device for performing a polar codes channel-aware procedure. The polar codes channel-aware procedure is provided for improving the error-correcting performance.

According to a first aspect of the present disclosure, a method for performing a polar codes channel-aware procedure is provided. A plurality of bit-channels have a polar code construction which is dynamic. The method includes the following steps. A plurality of reliability indices of some of the bit-channels are ranked. Whether an updating condition is satisfied is determined according to a ranking sequence of the reliability indices. If the updating condition is satisfied, the polar code construction is updated according to the ranking sequence of the reliability indices.

According to a second aspect of the present disclosure, a device for performing a polar codes channel-aware procedure is provided. A plurality of bit-channels have a polar code construction which is dynamic. The device includes a database and a controlling circuit. The database is for storing a plurality of reliability indices of some of the bit-channels. The controlling circuit is for updating the reliability indices according some of a plurality of output codes received from a decoding circuit, ranking the reliability indices, and updating the polar code construction according to a ranking sequence of the reliability indices, if an updating condition is satisfied.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a polar code scheme.

FIG. 2 illustrates one case that polar code scheme is channel-specific on the cells construction.

FIG. 3 shows a device for performing a polar codes channel-aware procedure according to a case of storage.

FIG. 4 shows a flowchart of a method for performing the polar codes channel-aware procedure according to the case of storage.

FIG. 5 illustrates the performance improvement of the polar codes channel-aware procedure.

FIG. 6 shows a device for performing the polar codes channel-aware procedure according to a case of communication.

FIG. 7 shows a flowchart of a method for performing the polar codes channel-aware procedure according to the case of communication.

### DETAILED DESCRIPTION

Preferred embodiments are disclosed below for elaborating the invention. A polar codes channel-aware procedure is provided for improving error-correcting performance. The following embodiments are for the purpose of elaboration only, not for limiting the scope of protection of the invention. Besides, secondary elements are omitted in the following embodiments to highlight the technical features of the invention.

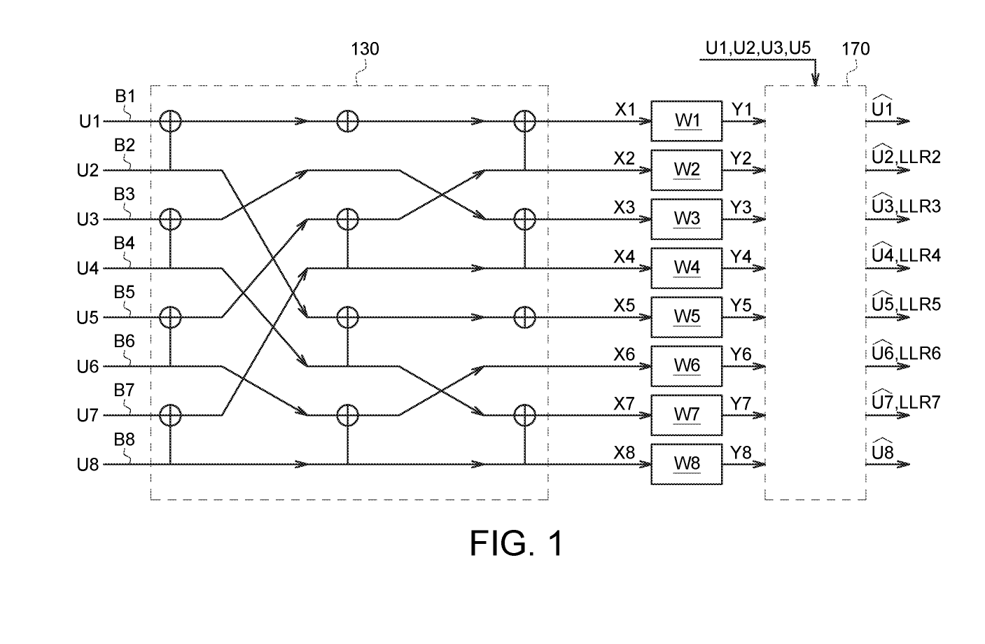

Please referring to FIG. 1, a polar code scheme is shown. In a case of storage, a plurality of cells W1 to W8 are polarized to be a plurality of bit-channels B1 to B8. For example, a plurality of input codes U1 to U8 are encoded to be a plurality of encoded codes X1 to X8 according to the following equations (1) to (8). Then, the encoded codes X1 to X8 are written into the cells W1 to W8. A plurality read codes Y1 to Y8 are read from the cells W1 to W8. The read codes Y1 to Y8 are allowed to be non-binary. Afterwards, the read codes Y1 to Y8 are decoded to obtain a plurality of output codes Û1 to Û8.

X1=U1⊕U2⊕U3⊕U4⊕U5⊕U6⊕U7⊕U8 (1)

X2=U5⊕U6⊕U7⊕U8 (2)

X3=U3⊕U4⊕U7⊕U8 (3)

X4=U7⊕U8 (4)

X5=U2⊕U4⊕U6⊕U8 (5)

X6=U6⊕U8 (6)

X7=U4⊕U8 (7)

X8=U8 (8)

According to the equations (1) to (8), the bit-channels B4, B6, B7, B8 have high reliability and the bit-channels B1, B2, B3, B5 have low reliability. Therefore, each of the bit-channels B4, B6, B7, B8 can be set at a data state which is used to be inputted an information, and each of the bit-channels B1, B2, B3, B5 can be set at a frozen state which is not used to be inputted the information. The setting of the data state and the frozen state on the bit-channels B1 to B8 is a polar code construction.

The polar code construction is channel-specific on the cells construction. A polar code construction which is suitable for one cells construction may not be suitable for another cells construction.

Concretely, once the state of the cells W1 to W8 changes, the polar code construction which is the setting of the data state and the frozen state on the bit-channels B1 to B8 may need to be changed as well to keep the error-correcting performance high. If the state of the cells W1 to W8 is not always identical and the polar code construction is not changed accordingly, part of the information may be stored via the bit-channels having low reliability and it will cause performance loss.

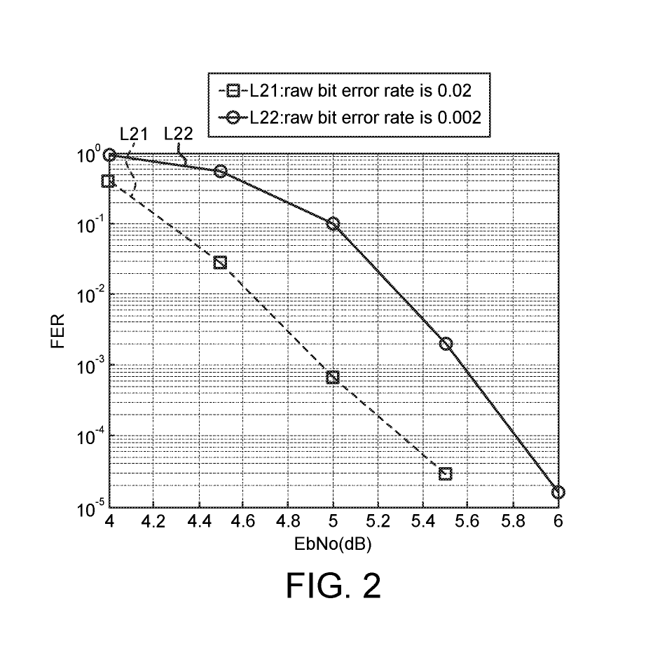

For example, a threshold voltage distribution of cells in a NAND flash memory may change as the number of P/E cycles increases or as the time passes by. Please refer to FIG. 2, which illustrates one case that polar code construction is channel-specific on the cells construction. As shown in FIG. 2, the code rate is 0.9, and the performance of a line L21 whose raw bit error rate is 0.02 is better than a line L22 whose raw bit error rate is 0.002. The performance gap of a frame error rate is about 1 to 2 order. If the polar code construction does not match the state of the cells, it will suffer from performance loss.

However, the estimation of the threshold voltage distribution of cells is quite difficult. In the case of storage, inaccurate programming, retention error, cell-to-cell interference, read disturb, program disturb and even temperature are the noise sources, precise estimation of the threshold voltage distribution of cells is almost impossible.

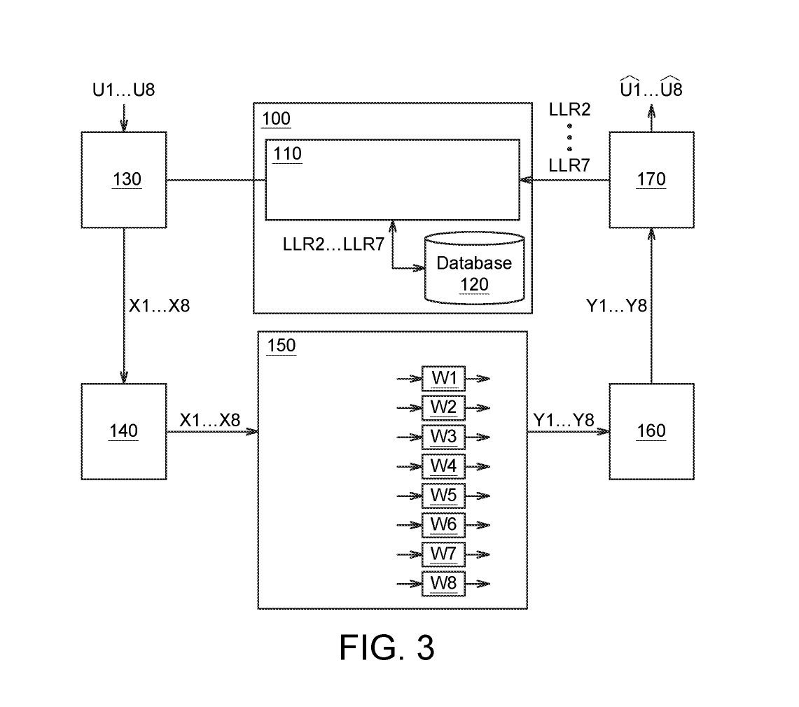

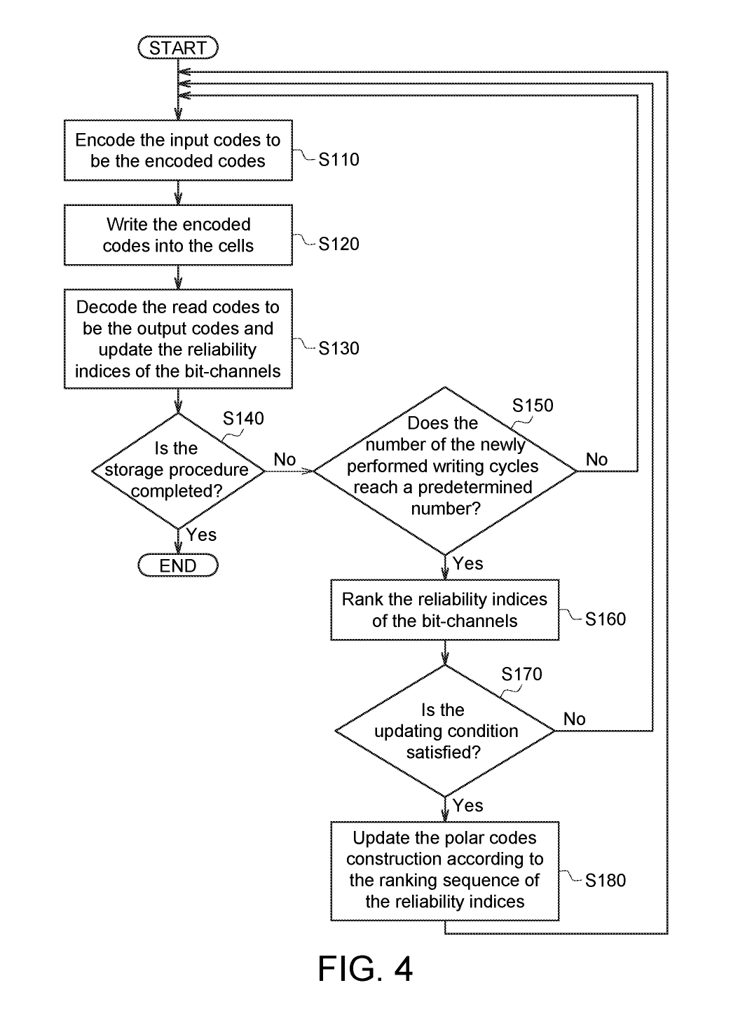

For increasing the performance, a method and a device for performing the polar codes channel-aware procedure are provided. Please refer to FIGS. 1, 3 and 4. FIG. 3 shows a device 100 for performing the polar codes channel-aware procedure according to the case of storage, and FIG. 4 shows a flowchart of a method for performing the polar codes channel-aware procedure according to the case of storage.

As shown in FIG. 3, the device 100 for performing the polar codes channel-aware procedure according to the case of storage includes a controlling circuit 110 and a database 120. In FIG. 1, the bit-channel B8 has highest reliability and is fixed at the data state. The bit-channel B1 has lowest reliability and is fixed at the frozen state. The bit-channels B2 to B7 can be changed between the data state and the frozen state in the polar codes channel-aware procedure. In this case, the code length is 8. The construction is quite deterministic and the changing may not be necessary. This case is an example for presenting. However, consider if the code length is large (e.g. 1024 or 16384), the changing is necessary to optimize error-correcting performance.

In step S110, an encoding circuit 130 encodes the input codes U1 to U8 to be the encoded codes X1 to X8.

In step S120, a writing circuit 140 writes the encoded codes X1 to X8 into the cells W1 to W8 in a storage circuit 150.

In step S130, a decoding circuit 170 decodes the read codes Y1 to Y8, which are read from the cells W1 to W8 by a reading circuit 160, to get the output codes Û1 to Û8, and the decoding circuit 170 updates the reliability indices LLR2-LLR7 of the input codes U2 to U7 to the controlling circuit 110 for updating the reliability of the bit-channels B2 to B7 when the updating condition is satisfied. Each of the reliability indices LLR2-LLR7 for input code U2 to U7 is an average of absolute value of a plurality of log-likelihood ratios for U2 to U7. The absolute value of the log-likelihood ratio for each bit-channel B2 to B7 can be viewed as a confidence coefficient. The reliability indices LLR2 to LLR7 are stored in the database 120.

In one embodiment, each of the read codes Y1 to Y8 is a soft information which is a combination of a plurality of read results via a plurality of different read voltages.

In step S140, the controlling circuit 110 determines whether the storage procedure is completed. If the storage procedure is completed, then the process is terminated; if the storage procedure is not completed, then the process proceeds to step S150.

In step S150, the controlling circuit 110 determines whether the number of the newly performed writing cycles reaches a predetermined number. In one writing cycle, all of the cells W1 to W8 are written one set of encoded codes X1 to X8. If the number of the newly performed writing cycles reaches the predetermined number, then the process proceeds to step S160; if the number of the newly performed writing cycles does not reach the predetermined number, then the process proceeds to step S110.

In step S160, the controlling circuit 110 ranks the reliability indices LLR2 to LLR7 of the bit-channels B2 to B7.

In step S170, the controlling circuit 110 determines whether an updating condition is satisfied according to a ranking sequence of the reliability indices LLR2 to LLR7. If the updating condition is satisfied, then the process proceeds to step S180; if the updating condition is not satisfied, then the process proceeds to step S110.

In this step, the updating condition is that the ranking sequence of the reliability indices LLR2 to LLR7 is changed and kept for a predetermined number of times, such as two times. That is to say, if the updating condition is satisfied, the change of the ranking sequence of the reliability indices LLR2 to LLR7 can be firmly confirmed.

In step S180, the controlling circuit 110 updates the polar code construction according to the ranking sequence of the reliability indices LLR2 to LLR7. For example, the previous ranking sequence of the reliability indices LLR2 to LLR7 is “LLR7, LLR6, LLR4, LLR5, LLR3, LLR2.” The reliability indices LLR7, LLR6, LLR4 of the bit-channel B7, B6, B4 are higher than the reliability indices LLR5, LLR3, LLR2 of the bit-channel B5, B3, B2, then the bit-channels B7, B6, B4 are set as the data state and the bit-channels B5, B3, B2 are set as the frozen state.

If the current ranking sequence of the reliability indices LLR2 to LLR7 is “LLR7, LLR6, LLR5, LLR4, LLR3, LLR2”, then the bit-channels B7, B6, B5 are set as the data state, and the bit-channels B4, B3, B2 are set as the frozen state. The bit-channel B4 is changed from the data state to the frozen state, and the bit-channel B5 is changed from the frozen state to the data state.

That is to say, the polar codes channel-aware procedure empirically modifies the polar code construction according to the reliability indices LLR2 to LLR7. Since the polar code construction matches the current states of the cells W1 to W8, it can improve error-correcting performance.

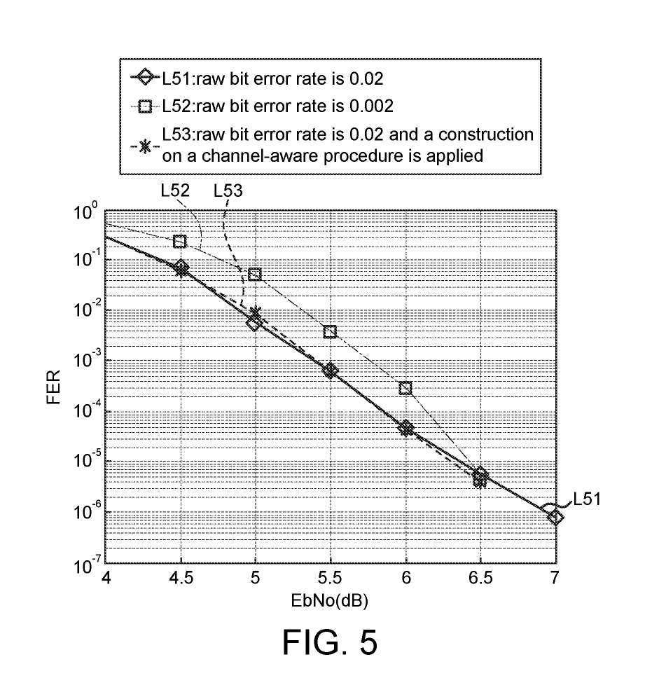

Please refer to FIG. 5. FIG. 5 illustrates the performance improvement of the polar codes channel-aware procedure. A line L51 and a line L52 denote the construction whose raw bit error rate are 0.02 and 0.002 respectively. As shown in FIG. 5, the performance of the line L51 is better than the line L52. A Line L53 denotes a construction on a channel-aware procedure whose raw bit error rate (RBER) is 0.02. The performance of the line L53 is improved about one order and almost close to the line L51.

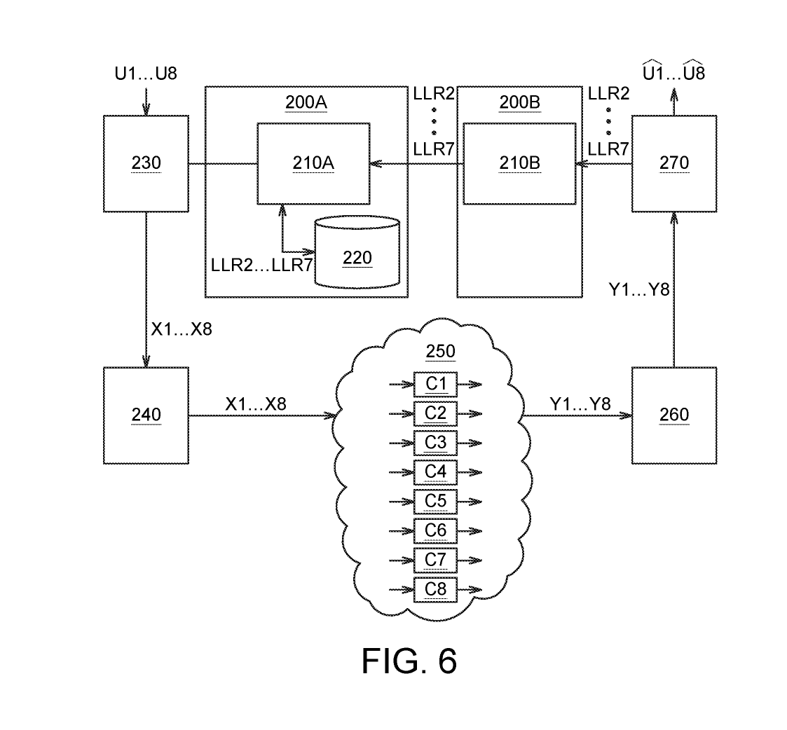

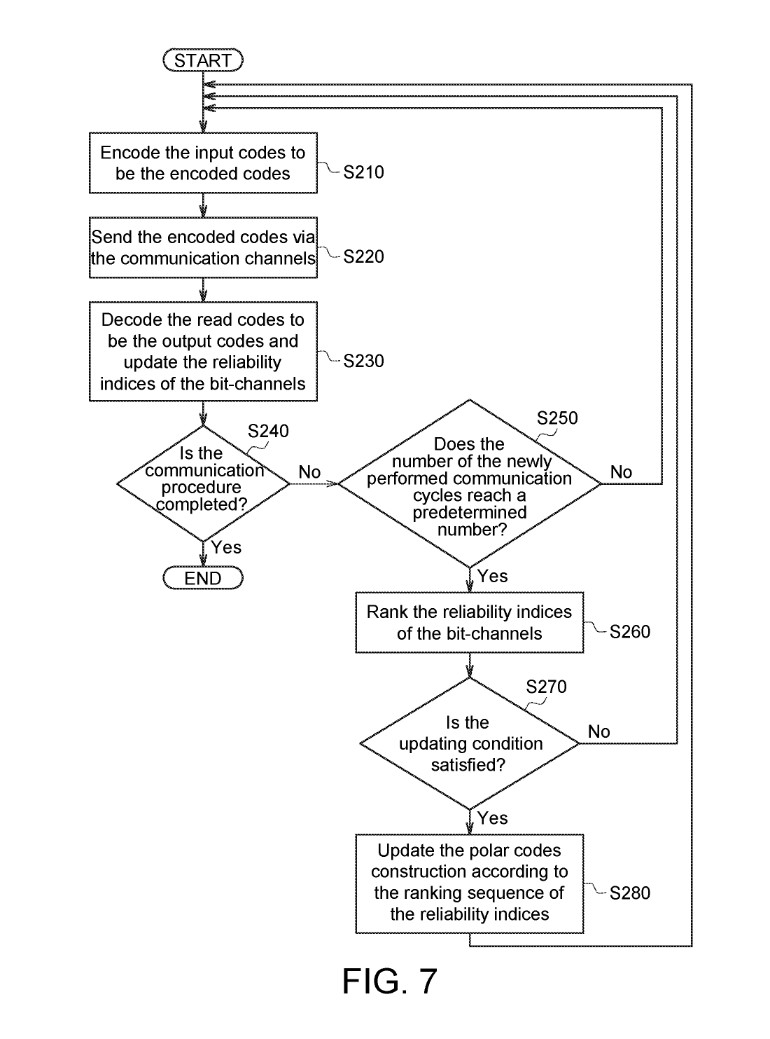

In other embodiment, the polar codes channel-aware procedure can be performed in the case of communication. In the case of communication, the prediction of channel states is much more difficult, since all obstacles, such as rain, temperature and moisture, are noise sources and make the channel state being changed. The inaccurate estimation of channel hurts the performance as well. Please refer to FIGS. 6 and 7. FIG. 6 shows a device 200A for performing the polar codes channel-aware procedure according to the case of communication, and FIG. 7 shows a flowchart of a method for performing the polar codes channel-aware procedure according to the case of communication.

As shown in FIG. 6, the device 200A for performing the polar codes channel-aware procedure according to the case of communication includes a controlling circuit 210A and a database 220. In step S210, an encoding circuit 230 encodes the input codes U1 to U8 to be the encoded codes X1 to X8.

In step S220, a sending circuit 240 sends the encoded codes X1 to X8 via a plurality of communication channels C1 to C8 in a network 250.

In step S230, a decoding circuit 270 decodes the read codes Y1 to Y8, which are read from the communication channels C1 to C8 by a receiving circuit 260, to get the output codes Û1 to Û8, and the decoding circuit 270 updates the reliability indices LLR-LLR7 of the input codes U2 to U7 to the controlling circuit 210 through to a controlling circuit 210B of a device 200B for updating the reliability of the bit-channels B2 to B7 when the updating condition is satisfied.

In step S240, the controlling circuit 210 determines whether the communication procedure is completed. If the communication procedure is completed, then the process is terminated; if the communication procedure is not completed, then the process proceeds to step S250.

In step S250, the controlling circuit 210 determines whether the number of the newly performed communication cycles reaches a predetermined number. In one communication cycle, one set of encoded codes X1 to X8 are transmitted via the communication channels C1 to C8. If the number of the newly performed communication cycles reaches the predetermined number, then the process proceeds to step S260; if the number of the newly performed communication cycles does not reach the predetermined number, then the process proceeds to step S210.

In step S260, the controlling circuit 210 ranks the reliability indices LLR2 to LLR7 of the bit-channels B2 to B7.

In step S270, the controlling circuit 210 determines whether the updating condition is satisfied according to the ranking sequence of the reliability indices LLR2 to LLR7. If the updating condition is satisfied, then the process proceeds to step S280; if the updating condition is not satisfied, then the process proceeds to step S210.

In step S280, the controlling circuit 210 updates the polar code construction according to the ranking sequence of the reliability indices LLR2 to LLR7.

That is to say, in the case of communication, the polar codes channel-aware procedure also empirically modifies the polar code construction according to the reliability indices LLR2 to LLR7. Since the polar code construction matches the current states of the communication channels C1 to C8, it can improve error-correcting performance.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for performing a polar codes channel-aware procedure, wherein a plurality of bit-channels have a polar code construction which is dynamic, and the method comprises:
ranking a plurality of reliability indices of some of the bit-channels;
determining whether an updating condition is satisfied according to a ranking sequence of the reliability indices; and
updating the polar code construction according to the ranking sequence of the reliability indices, if the updating condition is satisfied.

2. The method for performing the polar codes channel-aware procedure according to claim 1, further comprising:
encoding a plurality of input codes to be a plurality of encoded codes;
writing the encoded codes into a plurality of cells; and
decoding a plurality of read codes read from the cells to be a plurality of output codes, and updating the reliability indices according to some of the output codes.

3. The method for performing the polar codes channel-aware procedure according to claim 2, wherein each of the read codes is a soft information which is a combination of a plurality of read results via a plurality of different read voltages.

4. The method for performing the polar codes channel-aware procedure according to claim 1, further comprising:
encoding a plurality of input codes to be a plurality of encoded codes;
sending the encoded codes via a plurality of communication channels;
decoding a plurality of read codes received from the communication channels to be a plurality of output codes, and updating the reliability indices according to some of the output codes.

5. The method for performing the polar codes channel-aware procedure according to claim 1, wherein each of the reliability indices is an average of an absolute value of a plurality of log-likelihood ratios.

6. The method for performing the polar codes channel-aware procedure according to claim 1, wherein the updating condition is that the ranking sequence of the reliability indices is changed and kept for a predetermined number of times.

7. The method for performing the polar codes channel-aware procedure according to claim 1, wherein the updating condition is that the ranking sequence of the reliability indices is changed and kept for two times.

8. The method for performing the polar codes channel-aware procedure according to claim 1, wherein in the step of updating the polar code construction, at least one of the bit-channels is changed from a frozen state to a data state, and at least one of the bit-channel is changed from the data state to the frozen state.

9. The method for performing the polar codes channel-aware procedure according to claim 1, wherein after performing the step of updating the polar code construction, the number of the bit-channels which are at the data state is unchanged, and the number of the bit-channels which are at the frozen state is unchanged.

10. The method for performing the polar codes channel-aware procedure according to claim 1, wherein after performing the step of updating the polar code construction, the reliability index of any bit-channel which is at the data state is higher than the reliability index of any bit-channel which is at the frozen state.

11. A device for performing a polar codes channel-aware procedure, wherein a plurality of bit-channels have a polar code construction which is dynamic, and the device comprises:
a database for storing a plurality of reliability indices of some of the bit-channels; and
a controlling circuit for updating the reliability indices according to some of a plurality of output codes received from a decoding circuit, ranking the reliability indices, and updating the polar code construction according to a ranking sequence of the reliability indices, if an updating condition is satisfied.

12. The device for performing the polar codes channel-aware procedure according to claim 11, wherein
an encoding circuit is for encoding a plurality of input codes to be a plurality of encoded codes;
a writing circuit is for writing the encoded codes into a plurality of cells; and
the decoding circuit is for decoding a plurality of read codes read from the cells to be the output codes and for transmitting some of the output codes to the controlling circuit.

13. The device for performing the polar codes channel-aware procedure according to claim 12, wherein each of the read codes is a soft information which is a combination of a plurality of read results via a plurality of different read voltages.

14. The device for performing the polar codes channel-aware procedure according to claim 11, wherein
an encoding circuit is for encoding a plurality of input codes to be a plurality of encoded codes;
a sending circuit is for sending the encoded codes via a plurality of communication channels; and
the decoding circuit is for decoding a plurality of read codes received from the communication channels to be the output codes, and for transmitting some of the output codes to the controlling circuit.

15. The device for performing the polar codes channel-aware procedure according to claim 11, wherein each of the reliability indices is an average of an absolute value of a plurality of log-likelihood ratios.

16. The device for performing the polar codes channel-aware procedure according to claim 11, wherein the updating condition is that the ranking sequence of the reliability indices is changed and kept for a predetermined number of times.

17. The device for performing the polar codes channel-aware procedure according to claim 11, wherein the updating condition is that the ranking sequence of the reliability indices is changed and kept for two times.

18. The device for performing the polar codes channel-aware procedure according to claim 11, wherein the device changes at least one of the bit-channels from a frozen state to a data state, and changes at least one of the bit-channel from the data state to the frozen state.

19. The device for performing the polar codes channel-aware procedure according to claim 11, wherein after updating the polar code construction by the controlling circuit, the number of the bit-channels which are at the data state is unchanged, and the number of the bit-channels which are at the frozen state is unchanged.

20. The device for performing the polar codes channel-aware procedure according to claim 11, wherein after updating the polar code construction by the controlling circuit, the reliability index of any bit-channel which is at the data state is higher than the reliability index of any bit-channel which is at the frozen state.
